(19) United States
(12) Patent Application Publication
(10) Pub. No.: US 2006/0152624 A1
(43) Pub. Date: Jul. 13, 2006

(54) Method for generating a video pixel clock and an apparatus for performing the same

(75) Inventors: Soon-Jae Cho, Suwon-si (KR); Ki-Wan Lee, Hwaseong-si (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/324,725

(22) Filed: Jan. 2, 2006

(30) Foreign Application Priority Data
Jan. 7, 2005 (KR) 2005-1520

(51) Int. Cl. H04N 5/06; H03L 7/00

(52) U.S. Cl. 348/521; 348/537

(57) ABSTRACT

A method and apparatus for generating a video pixel clock are provided. The method includes generating a first clock having a frequency higher than a target frequency by providing an input pulse to a phase-locked loop, determining a number of erasures, and generating a second clock having the target frequency by preventing a transition of the first clock according to the number of erasures. The apparatus includes a phase-locked loop and a frequency adjustment unit. The phase-locked loop is configured to generate a first clock, which has a frequency higher than a target frequency, based on an input pulse. The frequency adjustment unit is configured to generate a second clock having the target frequency by preventing a transition of the first clock.

### CROSS-REFERENCE TO RELATED APPLICATION

This application claims priority under 35 USC § 119 to Korean Patent Application No. 2005-1520, filed on Jan. 7, 2005, the contents of which are incorporated by reference herein in their entirety.

### BACKGROUND OF THE INVENTION

1. Technical Field

The present invention relates to a display driver, and more particularly, to a method for generating a video pixel clock that may be used for a display driver and an apparatus for performing the same.

2. Discussion of the Related Art

Generally, a display driver is used to display images on a display device, such as a liquid crystal display (LCD), a plasma display panel (PDP), a cathode ray tube (CRT), a digital lighting processing (DLP) projection system, etc. To display images on such a device, the display driver uses an input digital signal or an input analog signal as well as synchronization signals to carry out driving control of the display device.

Because of the widespread adoption of digital image applications, such as digital television, the display driver should be capable of processing image signals in a variety of formats. For example, the display driver may need to process video signals in a National Television System Committee (NTSC) format, an Advanced Television System Committee (ATSC) format, an output format compatible with a digital set-top box, an output format compatible with a digital versatile disc (DVD), etc.

A video pixel clock is used by the display driver to generate a signal corresponding to each pixel of the display device. For example, in a DLP projection system having 1,280 pixels per horizontal line, the video pixel clock has 1,280 clock periods, each of which corresponds to each of the 1,280 pixels during a period of a horizontal synchronization signal.

FIG. 1 illustrates a conventional DLP display.

Referring to FIG. 1, the DLP display includes an active area 110 where an image is displayed and a blanking area 120 where an image is not displayed. In FIG. 1, the active area 110 has 1,280 pixels along a horizontal line and 720 pixels along a vertical line. As shown in FIG. 1, the display has a total resolution of 1,650×750 pixels. Thus, the blanking area 120 has 370 pixels along the horizontal line and 30 pixels along the vertical line.

It will be understood by one of ordinary skill in the art that a display for use with other display devices such as the LCD, PDP, etc., may also have an active area for displaying images and a blanking area where an image is not displayed.

An example resolution of an active area, a total resolution of a display and a frequency of a video pixel clock according to a refresh rate of approximately 60 Hz and a refresh rate of approximately 59.94 Hz are shown below in Table 1 for a variety of display devices.

TABLE 1

| | | | Clock | Clock | |
|---|---|---|---|---|---|
| | Active Pixels | Total Pixels | (60 Hz) | (59.94 Hz) | Remarks |
| 42″ | 1,024 × 768 | 1,125 × 800 | 54.0 | 53.946053 | |
| PDP | | | | | |
| 50″ | 1,366 × 768 | 1,450 × 775 | 67.425 | 67.357642 | |
| PDP | | | | | |
| LCD | 1,280 × 768 | | | | Flexible |
| DLP | 1,280 × 720 | 1,650 × 750 | 74.25 | 74.175824 | |
| CRT | 1,920 × 1,080 | 2,200 × 1,125 | 74.25 | 74.175824 | |
| STB | 720 × 480 | 858 × 525 | 54.54 | 54.0 | |

As can be observed from a review of Table 1, to drive a display of an LCD or, for example, the DLP projection system of FIG. 1, a display driver is needed that can support the 60 Hz refresh rate or the 59.94 Hz refresh rate. This is so because video signals received by the display may be produced in the NTSC format having the 59.94 Hz refresh rate or in a format having the 60 Hz refresh rate compatible with displaying a digital image.

For the display driver to generate a video pixel clock corresponding to the 60 Hz refresh rate or 59.94 Hz refresh rate, a phase-locked loop (PLL) having a high resolution is needed.

### SUMMARY OF THE INVENTION

An apparatus and method for generating a video pixel clock having a precise frequency using a phase-locked loop of a low resolution are provided.

In an exemplary embodiment of the present invention, a method of generating a video pixel clock includes: generating a first clock having a frequency higher than a target frequency by providing an input pulse to a phase-locked loop; determining a number of erasures; and generating a second clock having the target frequency by preventing a transition of the first clock according to the number of erasures.

The transition of the first clock may be prevented during a blanking period of a horizontal synchronization signal in which active data are not outputted. The number of erasures is determined for each horizontal line of a display.

The number of erasures corresponding to a horizontal line in close proximity to a center of the display is less than or equal to the number of erasures corresponding to a horizontal line farther away from the center of the display.

Determining the number of erasures includes: decreasing the number of erasures according to a decrease in a distance of a horizontal line from the center of the display in a front porch; increasing the number of erasures according to an increase in a distance of a horizontal line from the center of the display in a back porch; and maintaining the number of erasures for a horizontal line that is included in an active area where an image is displayed.

The number of erasures is determined by using first through fifth parameters, wherein: the first parameter denotes a maximum value of the number of erasures for the front porch; the second parameter denotes a variance in the number of erasures for the front porch; the third parameter denotes the number of erasures for each horizontal line included in the active area; the fourth parameter denotes a maximum value of the number of erasures for the back porch; and the fifth parameter denotes a variance in the number of erasures for the back porch.

The first clock has a frequency corresponding to a refresh rate of approximately 60 Hz and the second clock has a frequency corresponding to a refresh rate of approximately 59.94 Hz. The input pulse has a frequency of approximately 27 MHz.

In another exemplary embodiment of the present invention, a method of driving a display device includes generating a first clock having a frequency higher than a target frequency by providing an input pulse to a phase-locked loop; determining a number of erasures; generating a second clock having the target frequency by preventing a transition of the first clock according to the number of erasures during a blanking period of a horizontal synchronization signal in which active data are not outputted; and driving the display device using the second clock.

The number of erasures is determined for each horizontal line of a display of the display device.

The number of erasures corresponding to a horizontal line in close proximity to a center of the display is less than or equal to the number of erasures corresponding to a horizontal line farther away from the center of the display.

Determining the number of erasures includes: decreasing the number of erasures according to a decrease in a distance of a horizontal line from the center of the display in a front porch; increasing the number of erasures according to an increase in a distance of a horizontal line from the center of the display in a back porch; and maintaining the number of erasures for a horizontal line that is included in an active area where an image is displayed.

The number of erasures is determined by using first through fifth parameters, wherein: the first parameter denotes a maximum value of the number of erasures for the front porch; the second parameter denotes a variance in the number of erasures for the front porch; the third parameter denotes the number of erasures for each horizontal line included in the active area; the fourth parameter denotes a maximum value of the number of erasures for the back porch; and the fifth parameter denotes a variance in the number of erasures for the back porch.

The first clock has a frequency corresponding to a refresh rate of approximately 60 Hz and the second clock has a frequency corresponding to a refresh rate of approximately 59.94 Hz. The input pulse has a frequency of approximately 27 MHz.

In still another exemplary embodiment of the present invention, an apparatus for generating a video pixel clock includes a phase-locked loop configured to generate a first clock having a frequency higher than a target frequency based on an input pulse; and a frequency adjustment unit configured to generate a second clock corresponding to the target frequency by preventing a transition of the first clock.

The transition of the first clock is prevented during a blanking period of a horizontal synchronization signal in which active data are not outputted.

The transition of the first clock is prevented according to a number of erasures and the number of erasures is determined for each horizontal line of a display.

The number of erasures corresponding to a horizontal line in close proximity to a center of the display is less than or equal to the number of erasures corresponding to a horizontal line farther away from the center of the display.

In a front porch of the display, the number of erasures is decreased according to a decrease in a distance of a horizontal line from the center of the display, in a back porch of the display, the number of erasures is increased according to an increase in a distance of a horizontal line from the center of the display, and the number of erasures is maintained for a horizontal line that is included in an active area where an image is displayed.

The number of erasures is determined by using first through fifth parameters, wherein: the first parameter denotes a maximum value of the number of erasures for the front porch; the second parameter denotes a variance in the number of erasures for the front porch; the third parameter denotes the number of erasures for each horizontal line included in the active area; the fourth parameter denotes a maximum value of the number of erasures for the back porch; and the fifth parameter denotes a variance in the number of erasures for the back porch.

The first clock has a frequency corresponding to a refresh rate of approximately 60 Hz and the second clock has a frequency corresponding to a refresh rate of approximately 59.94 Hz.

The apparatus further includes a multiplexer for selecting one of an oscillation signal having a frequency of approximately 27 MHz and a pulse provided from an external device to generate the input pulse.

The apparatus further includes a voltage controlled crystal oscillator for generating the oscillation signal.

The second clock is the video pixel clock of a display driver for a liquid crystal display, plasma display panel, cathode ray tube display or a digital lighting processing projection system display.

### BRIEF DESCRIPTION OF THE DRAWINGS

The above and other features of the present invention will become more apparent to those of ordinary skill in the art by describing in detail exemplary embodiments thereof with reference to the attached drawings. Like reference characters refer to like elements throughout the drawings.

FIG. 1 illustrates a conventional DLP display.

FIG. 2 is a flowchart illustrating a method of generating a video pixel clock according to an exemplary embodiment of the present invention.

FIG. 3 is a timing diagram illustrating a method of generating a video pixel clock according to an exemplary embodiment of the present invention.

FIG. 4 illustrates a display divided according to an exemplary embodiment of the present invention.

FIG. 5 is a graph illustrating a number of erasures of horizontal lines according to an exemplary embodiment of the present invention.

FIG. 6 is a flowchart illustrating a method of driving a display device according to an exemplary embodiment of the present invention.

FIG. 7 is a block diagram illustrating an apparatus for generating a video pixel clock according to an exemplary embodiment of the present invention.

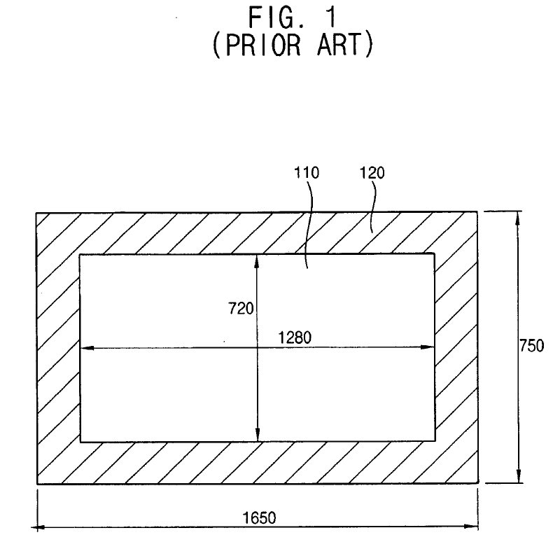

### DESCRIPTION OF EXEMPLARY EMBODIMENTS

Hereinafter, exemplary embodiments of the present invention will be explained in detail with reference to the accompanying drawings. However, specific structural and functional details disclosed herein are merely presented for purposes of describing the exemplary embodiments of the present invention.

It will be understood that, although the terms first, second, etc. may be used herein to describe various elements, these elements should not be limited by these terms. These terms are used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments and is not intended to be limiting of the invention. As used herein, the singular forms “a”, “an” and “the” are intended to include the plural forms as well, unless the context clearly indicates otherwise. It will be further understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

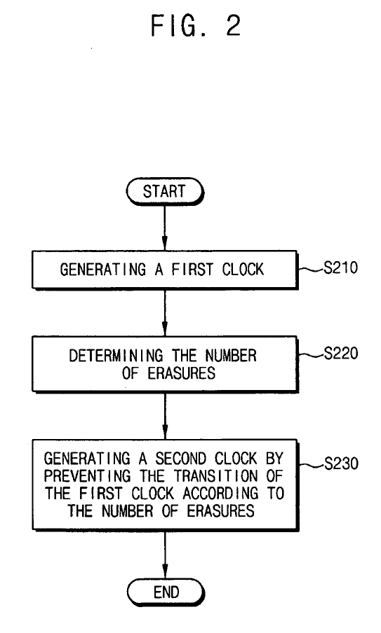

FIG. 2 is a flowchart illustrating a method of generating a video pixel clock according to an exemplary embodiment of the present invention.

Referring to FIG. 2, a first clock having a frequency higher than a target frequency is generated by providing an input pulse to a PLL (step S210).

The PLL may be a low resolution PLL. The input pulse may be provided from an external device or it may be generated by a display driver. In addition, the input pulse may be generated by using a voltage controlled crystal oscillator (VCXO).

A frequency of the input pulse may be, for example, 27 MHz and the first clock may have a frequency corresponding to a refresh rate of approximately 60 Hz.

Once the first clock has been generated, the number of erasures is determined (step S220).

It is to be understood by one of ordinary skill in the art that the number of erasures may be the number of clock periods during which the transition of the first clock is prevented. In other words, the number of erasures is the number of clock pulses removed from the first clock during, for example, a scanning period. The number of erasures may be determined for every horizontal line of a display.

After the number of erasures has been determined, a second clock corresponding to the target frequency is generated by preventing the transition of the first clock according to the number of erasures (step S230). In other words, when the number of erasures is set, for example, as nine for a particular horizontal line, the number of erasures indicates that nine clock pulses of the first clock are removed during a scanning period of the corresponding horizontal line.

The second clock may have a frequency corresponding to, for example, a refresh rate of approximately 59.94 Hz.

In step 230, the second clock may be generated to correspond to the horizontal line of a display. For example, when the horizontal line of the display has 1,280 pixels and rising edges of the second clock are used to control certain operations, the second clock may be generated such that the second clock has 1,280 rising edges corresponding to the horizontal line of the display.

In other words, when the number of erasures is set as nine with respect to the horizontal line having 1,280 pixels, it indicates that the first clock having 1,289 clock periods during a one-frame period (or a time period corresponding to one frame) is converted to the second clock having 1,280 clock periods during the one-frame period.

It should also be noted that in an alternate embodiment, the steps illustrated in FIG. 2 may occur out of the order just described. For example, the steps in FIG. 2 may be performed in a reverse order or simultaneously.

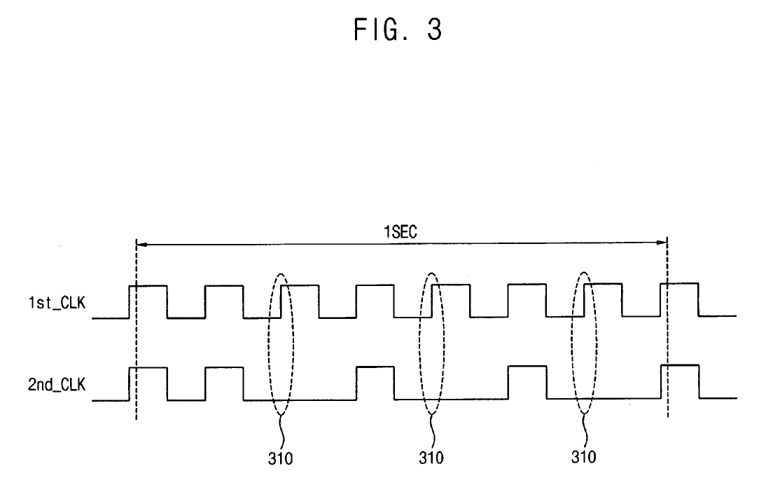

FIG. 3 is a timing diagram illustrating a method of generating a video pixel clock according to an exemplary embodiment of the present invention.

Referring to FIG. 3, pulses of a first clock 1^{st}_CLK are removed by the number of erasures, which in this example is ‘3’, to generate a second clock 2^{nd}_CLK. In other words, since the number of erasures is ‘3’, three rising transitions 310 of the first clock 1^{st}_CLK are prevented and the second clock 2^{nd}_CLK is generated without having the pulses indicated by the rising transitions 310.

For example, in FIG. 3, the first clock 1^{st}_CLK has seven rising edges during one second (1 sec) while the second clock 2^{nd}_CLK has four rising edges during the same period of time. The rising transitions 310 of the first clock 1^{st}_CLK may be removed by, for example, performing an AND operation of the first clock 1^{st}_CLK and logic “0” in a selected clock period.

In another example, when the clock period is counted based on the rising edge of the first clock 1^{st}_CLK, and the first clock 1^{st}_CLK has a frequency of 7 Hz, the second clock 2^{nd}_CLK has a frequency of 4 Hz. This is so because three clock pulses of the first clock 1^{st}_CLK having a frequency of 7 Hz have been removed based on the number of erasures ‘3’, thus the second clock 2^{nd}_CLK having a frequency of 4 Hz is generated.

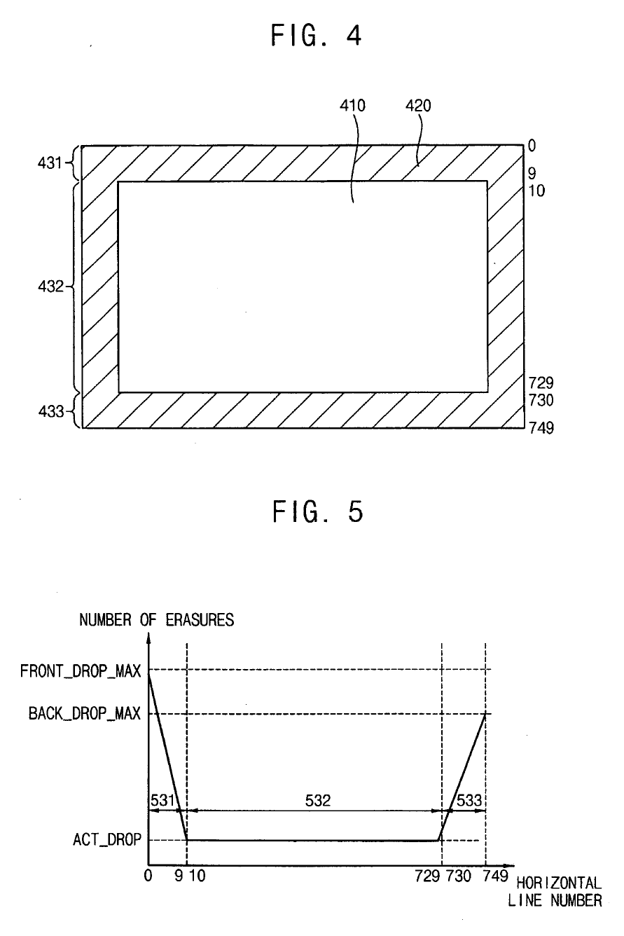

FIG. 4 illustrates a display divided according to an exemplary embodiment of the present invention.

Referring to FIG. 4, the display may be divided into a front porch 431, and a back porch 433, with horizontal lines 432 that are included in both an active area 410 and a blanking area 420 located therebetween.

As shown in FIG. 4, the front porch 431 and the back porch 433 are disposed at upper and lower portions of the display and at opposite sides of the active area 410. For example, when the display includes 750 horizontal lines as shown in FIG. 4, the front porch 431 includes horizontal lines 0 to 9 and the back porch 433 includes horizontal lines 730 to 749. The horizontal lines in the active area 410 may correspond to horizontal lines 10 to 729.

In an alternative embodiment, the horizontal lines 432 of the active area 410 may correspond to a lesser number of lines and thus the front and back porches 431 and 433 may correspond to a greater number of horizontal lines according to a distance of the horizontal lines from the top or bottom of the display.

In the method of generating the video pixel clock according to an exemplary embodiment of the present invention, the second clock 2^{nd}_CLK is generated by preventing the transitions of the first clock 1^{st}_CLK during a time interval corresponding to the blanking area 420. For example, the second clock 2^{nd}_CLK is generated by preventing the transition of the first clock 1^{st}_CLK during a time interval corresponding to one of a portion of the blanking area 420 of the horizontal lines 432, the front porch 431 and the back porch 433. Otherwise, the transitions of the first clock 1^{st}_CLK may be prevented during an active period of a horizontal synchronization signal in which active data are outputted, and the quality of displayed images may be degraded.

Also in the method of generating the video pixel clock according to an exemplary embodiment of the present invention, the number of erasures for the horizontal lines of the front porch 431 or the back porch 433 may be decreased as the distance of the horizontal lines of the front porch 431 or the back porch 433 from the active area 410 is decreased. In addition, the number of erasures may remain constant with respect to the horizontal lines 432 included in the active area 410.

By doing this, displayed images may not be as degraded when the transitions of the first clock 1^{st}_CLK are prevented during an active period of the horizontal synchronization signal in which active data are outputted.

The number of erasures may be determined by using the parameters shown in Table 2 below.

TABLE 2

| NAME | DESCRIPTION |
|---|---|
| FRONT_DROP_MAX | Maximum Value of the Number of |
| | Erasures for Front Porch |
| FRONT_DROP_INT | Variance in the Number of |
| | Erasures for Front Porch |
| ACT_DROP | The Number of Erasures for a |
| | Horizontal Line Included in an |
| | Active Area |
| BACK_DROP_MAX | Maximum Value of the Number of |
| | Erasures for Back Porch |
| BACK_DROP_INT | Variance in the Number of |
| | Erasures for Back Porch |

As shown in Table 2, the parameter FRONT_DROP_MAX indicates the maximum number of erasures of the front porch 431. In other words, the parameter FRONT_DROP_MAX may correspond to the number of erasures of a horizontal line disposed at the top of the display. The value of the parameter FRONT_DROP_MAX may be, for example, an integer between 0 and 63.

The parameter FRONT_DROP_INT indicates a variance in the number of erasures of the front porch 431. Therefore, the number of erasures of one of the horizontal lines of the front porch 431 may be determined by using the number of erasures of an adjacent horizontal line and the parameter FRONT_DROP_INT. For example, the number of erasures of the horizontal line of the front porch 431 may be decreased by the value of the parameter FRONT_DROP_INT as the horizontal line number is increased one by one (e.g., by moving downward line by line on the display). The value of the parameter FRONT_DROP_INT may be, for example, an integer between 0 and 7.

The parameter ACT_DROP indicates the number of erasures of each of the horizontal lines 432 included in the active area 410. In other words, the horizontal lines 432 included in the active area 410 have substantially the same number of erasures. Referring back to FIG. 4, the transition of the first clock 1^{st}_CLK for the horizontal lines 432 included in the active area 410 may be performed during a blanking period of the horizontal synchronization signal in which active data are not outputted. The value of the parameter ACT_DROP may be, for example, an integer between 0 and 3.

The parameter BACK_DROP_MAX indicates the maximum number of erasures of the back porch 433. The parameter BACK_DROP_MAX may also correspond to the number of erasures of one of the horizontal lines disposed at the bottom of the display. The value of the parameter BACK_DROP_MAX may be, for example, an integer between 0 and 63.

The parameter BACK_DROP_INT indicates the variance in the number of erasures of the back porch 433. Therefore, the number of erasures of one of the horizontal lines of the back porch 433 may be determined using the number of erasures of an adjacent horizontal line and the parameter BACK_DROP_INT. For example, the number of erasures of the horizontal line of the back porch 433 may be increased by the value of the parameter BACK_DROP_INT as the horizontal line number is increased one by one (e.g., moving downward line by line on the display). The value of the parameter BACK_DROP_INT may be, for example, an integer between 0 and 7.

FIG. 5 is a graph illustrating the number of erasures of a horizontal line determined by the parameters of Table 1 according to an exemplary embodiment of the present invention.

Referring to FIG. 5, the number of erasures for one of the horizontal lines of a front porch 531 is linearly decreased according to an increase of the horizontal line number. Specifically, the number of erasures corresponding to the front porch 531 is decreased from the value of the parameter FRONT_DROP_MAX to the value of the parameter ACT_DROP according to an increase in the horizontal line number. The decrease of the number of erasures may correspond to the value of the parameter FRONT_DROP_INT, or ((FRONT_DROP_MAX−BACK_DROP_MAX)/(NUMBER OF THE HORIZONTAL LINES)).

The number of erasures of the horizontal line of the front porch 531 that is in close proximity to, for example, the active area 410 of FIG. 4, is similar to that of the horizontal lines 432 (or 532 as shown in FIG. 5) included in the active area 410. Alternatively, the number of erasures corresponding to the front porch 531 may be set to decrease according to the increase in the horizontal line number until the number of erasures reaches a value greater than the parameter ACT_DROP to maintain the value.

With respect to the horizontal lines 432 or 532 that are included in the active area 410, the number of erasures may be substantially maintained at the value of the parameter ACT_DROP. In addition, the number of erasures of the horizontal lines 432 or 532 included in the active area 410 may be less than or equal to the number of erasures of the horizontal lines in the front porch 531 or a back porch 533.

Still referring to FIG. 5, the number of erasures for the horizontal line of the back porch 533 is linearly increased according to an increase of the horizontal line number. Specifically, the number of erasures corresponding to the back porch 533 is increased from the value of the parameter ACT_DROP to the value of the parameter BACK_DROP_MAX according to an increase in the horizontal line number. The increase of the number of erasures corresponds to the value of the parameter BACK_DROP_INT or ((BACK_DROP_MAX−ACT_DROP)/(NUMBER OF THE HORIZONTAL LINES)).

The number of erasures of the horizontal line of the back porch 533 that is in relatively close proximity to the active area 410 is similar to the number of erasures of each of the horizontal lines 432 or 532 included in the active area 410. Alternatively, the number of erasures corresponding to the back porch 533 may be set to increase according to the increase in the horizontal line number until the number of erasures reaches a value less than the parameter BACK_DROP_MAX to maintain the value.

A method of generating the video pixel clock according to an exemplary embodiment of the present invention will now be described in more detail with respect to a screen having 750 horizontal lines as shown in FIGS. 4 and 5.

In the method, a first clock may have a frequency of approximately 74.25 MHz, which corresponds to the 60 Hz refresh rate of the display. The first clock may be generated by a PLL having a low resolution.

The parameters shown above in Table 2 may be set as shown in Table 3.

TABLE 3

| | |
|---|---|
| FRONT_DROP_MAX | 21 |
| FRONT_DROP_INT | 2 |
| ACT_DROP | 1 |
| BACK_DROP_MAX | 29 |
| BACK_DROP_INT | 2 |

According to the parameters set in Table 3, the number of erasures for each respective horizontal line of the front porch 431 or 531 may be determined according to the values shown below in Table 4.

TABLE 4

| # of Horizontal Line | # of Erasures |
|---|---|
| 0 | 21 |
| 1 | 19 |
| 2 | 17 |
| 3 | 15 |
| 4 | 16 |
| 5 | 11 |
| 6 | 9 |
| 7 | 7 |
| 8 | 5 |
| 9 | 3 |

With respect to the horizontal lines 432 or 532 included in the active area 410, the numbers of erasures may be determined as shown in Table 5.

TABLE 5

| # of Horizontal Line | # of Erasures |
|---|---|
| 10˜729 | 1 |

With respect to the horizontal lines of the back porch 433 or 533, the number of erasures may be determined as shown in Table 6.

TABLE 6

| # of Horizontal Line | # of Erasures |
|---|---|
| 730 | 3 |
| 731 | 5 |
| 732 | 7 |
| 733 | 9 |
| 734 | 11 |
| 735 | 13 |
| 736 | 15 |
| 737 | 17 |
| 738 | 19 |
| 739 | 21 |
| 740 | 23 |
| 741 | 25 |
| 742 | 27 |
| 743 | 29 |
| 744 | 29 |
| 745 | 29 |
| 746 | 29 |
| 747 | 29 |
| 748 | 29 |
| 749 | 29 |

Referring now to Table 4 through Table 6, the number of erasures assigned to the front porch 431 or 531 for one frame is calculated as 21+19+17+15+13+11+9+7+5+3, e.g., 120, the number of erasures assigned to the horizontal line included with the active area 410 is calculated as 1×720, e.g., 720, and the number of erasures assigned to the back porch 433 or 533 for one frame is calculated as 3+5+7+9+11+13+15+17+19+21+23+25+27+29+29+29+29+29+29+29, e.g., 398. Therefore, a total of number of the erasures for one frame is calculated as 120+720+398=1,238.

Thus, when 60 frames are outputted in one second, the number of erasures during one second is 60×1,238=74,280. In other words, 74,280 rising edges among 74.25×10⁶ rising edges of the first clock 1^{st}_CLK are prevented during one second to generate the second clock having 74.25×10⁶−74,280, e.g., 74,175,720 rising edges during one second. Therefore, the second clock 2^{nd}_CLK may have a frequency of 74.175720 MHz.

In addition, the second clock 2^{nd}_CLK may have a frequency corresponding to a 59.94 MHz refresh rate. For example, although the frequency (e.g., 74.175720 MHz) of the second clock 2^{nd}_CLK may have an error of about +/−104 Hz from the frequency of 74.175824 MHz corresponding to the 59.94 MHz refresh rate as shown above in Table 1, this amount of error may be acceptable in certain video applications.

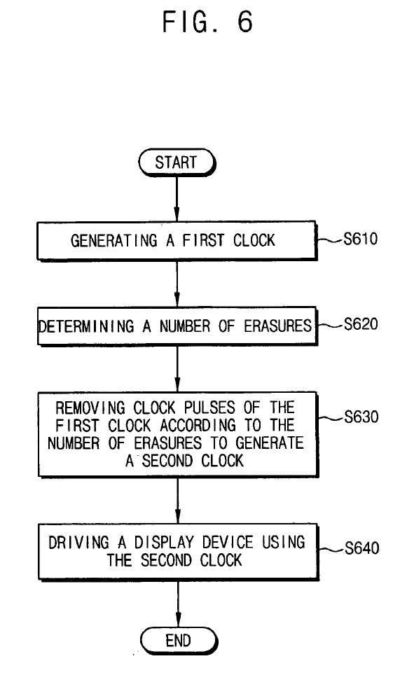

FIG. 6 is a flowchart illustrating a method of driving a display device according to an exemplary embodiment of the present invention. Since steps S610 through S630 of FIG. 6 are similar to or the same as steps S210 through S230 of FIG. 2, a detailed description thereof will be omitted.

Referring to FIG. 6, an input pulse is provided to a PLL to generate a first clock CLK1 having a frequency higher than a target frequency (step S610).

The PLL may be a low resolution PLL. The input pulse may be applied from an external device, or generated by the PLL.

The first clock CLK1 may have a frequency corresponding to, for example, the 60 Hz refresh rate.

Once the first clock CLK1 has been generated, the number of erasures is determined (step S620).

The number of erasures is the number of clock periods during which the transition of the first clock CLK1 is prevented. In other words, the number of erasures is the number of clock pulses that are removed from the first clock CLK1 during, for example, a scanning period. The number of erasures may be determined for each horizontal line of the display.

After the number of erasures has been determined, a second clock CLK2 having the target frequency is generated by preventing the transition of the first clock CLK1 according to the number of erasures (step S630). In other words, clock pulses of the first clock CLK1 are removed according to the number of erasures to generate the second clock CLK2. The second clock may have a frequency corresponding to, for example, the 59.94 Hz refresh rate.

Now that the second clock CLK2 has been generated, the display device is driven by the second clock CLK2 (step S640).

In step 640, the display device may perform any type of operation that is executed by a typical display driver using a video pixel clock. In addition, the display device may be driven by any type of processor. For example, the display device may be driven by a video graphics processor and an analog display processor to display images on the display of FIG. 4.

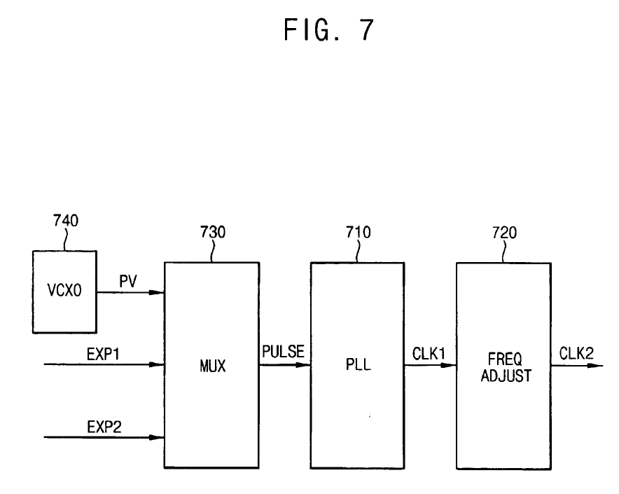

FIG. 7 is a block diagram illustrating an apparatus for generating a video pixel clock according to an exemplary embodiment of the present invention.

Referring to FIG. 7, the video pixel clock generating apparatus includes a PLL 710, a frequency adjustment unit 720, a multiplexer (MUX) 730 and a VCXO 740.

As shown in FIG. 7, the PLL 710 generates a first clock CLK1 having a frequency higher than a target frequency based on an input pulse PULSE. The PLL 710 may be a low resolution PLL. The input pulse PULSE may be applied from an external device, the MUX 730 or generated in the PLL 710.

The first clock CLK1 may have a frequency corresponding, for example, to the 60 Hz refresh rate.

The frequency adjustment unit 720 generates a second clock CLK2 having a frequency corresponding to the target frequency by preventing the transition of the first clock CLK1 based on the number of erasures.

For example, the frequency adjustment unit 720 may generate the video pixel clock by performing an operation in step S220 and step S230 described with reference to FIG. 2 or in steps S620 and S630 described with reference to FIG. 6.

More specifically, the frequency adjustment unit 720 may be coded to perform the operations illustrated in FIGS. 2 through 6 by using, for example, a hardware description language (HDL) that is implemented in hardware by an application-specific integrated circuit (ASIC) included in the frequency adjustment unit 720. Alternatively, the frequency adjustment unit 720 may be implemented in software or by a combination of software and hardware.

The VCXO 740 may generate an oscillation signal (PV) having a frequency of about 27 MHz and may be implemented on a display driver chip.

The multiplexer (MUX) 730 may selectively generate the input pulse PULSE by using one of the oscillation signal (PV) from the VCXO 740 and pulses EXP1 and EXP2 that are externally applied.

Although the video pixel clock generating apparatus has been shown with the MUX 730 and VCXO 740, the video pixel clock generating apparatus may be configured such that the MUX 730 and VCXO 740 are not included therein.

In the method and apparatus for generating the video pixel clock according to an exemplary embodiment of the present invention, a clock may be generated by using a PLL having a low resolution and the transition of the clock may thus be prevented so that the video pixel clock having a desired frequency is generated. Therefore, accurate video pixel clocks may be efficiently generated by using the PLL having a low resolution to allow a simpler implementation and reduced PLL chip size. In addition, the cost of manufacturing a display driver including the PLL may be reduced.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of generating a video pixel clock, comprising:
generating a first clock having a frequency higher than a target frequency by providing an input pulse to a phase-locked loop;
determining a number of erasures; and
generating a second clock having the target frequency by preventing a transition of the first clock according to the number of erasures.

2. The method of claim 1, wherein generating the second clock includes,
preventing the transition of the first clock during a blanking period of a horizontal synchronization signal in which active data are not outputted.

3. The method of claim 2, wherein the number of erasures is determined for each horizontal line of a display.

4. The method of claim 3, wherein the number of erasures corresponding to a horizontal line in close proximity to a center of the display is less than or equal to the number of erasures corresponding to a horizontal line farther away from the center of the display.

5. The method of claim 4, wherein determining the number of erasures includes:
decreasing the number of erasures according to a decrease in a distance of a horizontal line from the center of the display in a front porch;
increasing the number of erasures according to an increase in a distance of a horizontal line from the center of the display in a back porch; and
maintaining the number of erasures for a horizontal line that is included in an active area where an image is displayed.

6. The method of claim 5, wherein the number of erasures is determined by using first through fifth parameters, wherein:
the first parameter denotes a maximum value of the number of erasures for the front porch;
the second parameter denotes a variance in the number of erasures for the front porch;
the third parameter denotes the number of erasures for each horizontal line included in the active area;
the fourth parameter denotes a maximum value of the number of erasures for the back porch; and
the fifth parameter denotes a variance in the number of erasures for the back porch.

7. The method of claim 1, wherein the first clock has a frequency corresponding to a refresh rate of approximately 60 Hz and the second clock has a frequency corresponding to a refresh rate of approximately 59.94 Hz.

8. The method of claim 1, wherein the input pulse has a frequency of approximately 27 MHz.

9. A method of driving a display device, comprising:
generating a first clock having a frequency higher than a target frequency by providing an input pulse to a phase-locked loop;
determining a number of erasures;
generating a second clock having the target frequency by preventing a transition of the first clock according to the number of erasures during a blanking period of a horizontal synchronization signal in which active data are not outputted; and
driving the display device using the second clock.

10. The method of claim 9, wherein the number of erasures is determined for each horizontal line of a display of the display device.

11. The method of claim 10, wherein the number of erasures corresponding to a horizontal line in close proximity to a center of the display is less than or equal to the number of erasures corresponding to a horizontal line farther away from the center of the display.

12. The method of claim 11, wherein determining the number of erasures includes:
decreasing the number of erasures according to a decrease in a distance of a horizontal line from the center of the display in a front porch;
increasing the number of erasures according to an increase in a distance of a horizontal line from the center of the display in a back porch; and
maintaining the number of erasures for a horizontal line that is included in an active area where an image is displayed.

13. The method of claim 12, wherein the number of erasures is determined by using first through fifth parameters, wherein:
the first parameter denotes a maximum value of the number of erasures for the front porch;
the second parameter denotes a variance in the number of erasures for the front porch;
the third parameter denotes the number of erasures for each horizontal line included in the active area;
the fourth parameter denotes a maximum value of the number of erasures for the back porch; and
the fifth parameter denotes a variance in the number of erasures for the back porch.

14. The method of claim 9, wherein the first clock has a frequency corresponding to a refresh rate of approximately 60 Hz and the second clock has a frequency corresponding to a refresh rate of approximately 59.94 Hz.

15. The method of claim 9, wherein the input pulse has a frequency of approximately 27 MHz.

16. An apparatus for generating a video pixel clock, comprising:
a phase-locked loop configured to generate a first clock having a frequency higher than a target frequency based on an input pulse; and
a frequency adjustment unit configured to generate a second clock corresponding to the target frequency by preventing a transition of the first clock.

17. The apparatus of claim 16, wherein the transition of the first clock is prevented during a blanking period of a horizontal synchronization signal in which active data are not outputted.

18. The apparatus of claim 17, wherein the transition of the first clock is prevented according to a number of erasures and the number of erasures is determined for each horizontal line of a display.

19. The apparatus of claim 18, wherein the number of erasures corresponding to a horizontal line in close proximity to a center of the display is less than or equal to the number of erasures corresponding to a horizontal line farther away from the center of the display.

20. The apparatus of claim 19, wherein, in a front porch of the display, the number of erasures is decreased according to a decrease in a distance of a horizontal line from the center of the display, in a back porch of the display, the number of erasures is increased according to an increase in a distance of a horizontal line from the center of the display, and the number of erasures is maintained for a horizontal line that is included in an active area where an image is displayed.

21. The apparatus of claim 20, wherein the number of erasures is determined by using first through fifth parameters, wherein:
the first parameter denotes a maximum value of the number of erasures for the front porch;
the second parameter denotes a variance in the number of erasures for the front porch;
the third parameter denotes the number of erasures for each horizontal line included in the active area;
the fourth parameter denotes a maximum value of the number of erasures for the back porch; and
the fifth parameter denotes a variance in the number of erasures for the back porch.

22. The apparatus of claim 16, wherein the first clock has a frequency corresponding to a refresh rate of approximately 60 Hz and the second clock has a frequency corresponding to a refresh rate of approximately 59.94 Hz.

23. The apparatus of claim 16, further comprising:
a multiplexer for selecting one of an oscillation signal having a frequency of approximately 27 MHz and a pulse provided from an external device to generate the input pulse.

24. The apparatus of claim 23, further comprising:
a voltage controlled crystal oscillator for generating the oscillation signal.

25. The apparatus of claim 16, wherein the second clock is the video pixel clock of a display driver for a liquid crystal display, plasma display panel, cathode ray tube display or a digital lighting processing projection system display.
